(19) United States
(12) Patent Application Publication
(10) Pub. No.: US 2025/0388455 A1
(43) Pub. Date: Dec. 25, 2025

(54) MEMS DEVICE HAVING A TILTABLE STRUCTURE AND QUASI-STATIC PIEZOELECTRIC ACTUATION, IN PARTICULAR MICROMIRROR, WITH IMPROVED EFFICIENCY

(71) Applicant: STMicroelectronics International N.V., Geneva (CH)

(72) Inventors: Giacomo FERRARI, Broni (IT); Roberto CARMINATI, Piancogno (IT); Massimiliano MERLI, Stradella (IT)

(73) Assignee: STMicroelectronics International N.V., Geneva (CH)

(21) Appl. No.: 19/208,404

(22) Filed: May 14, 2025

(30) Foreign Application Priority Data
Jun. 19, 2024 (IT) 102024000014038

(51) Int. Cl. B81B 3/00; G02B 26/08; G02B 26/10

(52) U.S. Cl. CPC B81B 3/0043; G02B 26/0858; G02B 26/105; B81B 2201/032; B81B 2201/042; B81B 2203/0154; B81B 2203/0163; B81B 2203/0307; B81B 2203/0315; B81B 2203/058

(57) ABSTRACT

Microelectronic device of piezoelectric type, wherein a first and a second actuation unit are coupled between a fixed structure and a tiltable structure, on a first side of a rotation axis to control the rotation of the tiltable structure around the first rotation axis. Each actuation unit is formed by a first actuator, a second actuator and an elastic system. Each elastic system mutually couples the free ends of the respective first and second actuators to the tiltable structure.

### BACKGROUND

### Technical Field

The present disclosure relates to a microelectromechanical device.

### Description of the Related Art

Microelectromechanical mirror devices are used in portable apparatuses, such as smartphones, tablets, notebooks, PDAs, for optical applications, in particular for directing light radiation beams generated by a light source in desired manner, for projecting images at a distance. By virtue of the reduced size, these devices allow to meet stringent requirements as regards occupation of space, in terms of area and thickness.

For instance, microelectromechanical mirror devices are used in miniaturized projector apparatuses (so-called pico-projectors) incorporated in or coupled to portable devices, which are able to project images at a distance and generate desired light patterns.

Microelectromechanical mirror devices generally include a mirror structure of a reflecting material, elastically supported above a cavity and manufactured from a body of semiconductor material so as to be movable, for example with a tilting or rotation movement out of a corresponding main extension plane, to direct an incident light beam in a desired manner.

The rotation of the tiltable structure is controlled through an actuation system which may, for example, be of an electrostatic, electromagnetic or piezoelectric type.

Among them, microelectromechanical mirror devices with piezoelectric actuation have the advantage of requiring lower actuation voltages and power consumption than devices with electrostatic or electromagnetic actuation. Furthermore, in microelectromechanical mirror devices with piezoelectric actuation, piezoresistive sensors adapted to sense the operating condition of the mirror and provide a feedback signal to allow feedback control of the actuation. Hereinafter, reference will therefore be made to a piezoelectric actuator.

Typically, in these devices, a deviation of the light beam along two axes is requested, which may be obtained by two cascaded MEMS mirror devices of a uniaxial-type, or by a single microelectromechanical mirror device of a biaxial-type.

For example, Italian patent 102022000004745 (corresponding to European publication EP 4242724 and to US patent application US 2023/288696) describes a microelectromechanical mirror device having an internal frame arranged above a cavity and defining a window; a rotatable platform has a reflecting surface, is arranged in the window and is elastically coupled to the internal frame by coupling elastic elements; an actuation structure is coupled to the internal frame so as to cause the rotation, in a decoupled manner, of the rotatable platform around a first and a second rotation axis.

In these devices, it is desired to have wide deflection angles of the rotatable platform. In general, this may be obtained by increasing the size of the piezoelectric structures. However, beyond a certain limit, increasing the size does not translate into a wider deflection angle, since a greater area determines a higher increase in stiffness than the increase in obtainable force, thus resulting in a worsening of the deflection capacities.

The present disclosure provides a MEMS device of piezoelectric type with improved performances, especially as regards efficiency and possibility of obtaining wide deflection angles.

### BRIEF SUMMARY

According to the present disclosure, a piezoelectric microelectromechanical device (made by using MEMS-Micro-Electro-Mechanical System-technology) device is provided. The microelectromechanical device has a tiltable structure and quasi-static piezoelectric actuation, with improved efficiency. Hereinafter reference will be made, without thereby losing generality, to a MEMS mirror device in which the tiltable structure carries a reflecting surface.

The Microelectronic device includes a first and a second actuation unit that are coupled between a fixed structure and a tiltable structure, on a first side of a rotation axis to control the rotation of the tiltable structure around the first rotation axis. Each actuation unit is formed by a first actuator, a second actuator, and an elastic system. Each elastic system mutually couples the free ends of the respective first and second actuators to the tiltable structure.

### BRIEF DESCRIPTION OF THE SEVERAL VIEWS OF THE DRAWINGS

For a better understanding of the present disclosure, some embodiments thereof are now described, purely by way of non-limiting example, with reference to the attached drawings, wherein:

FIG. 1 is a schematic top-plan representation of an embodiment of the present microelectromechanical mirror device;

FIG. 2 illustrates an enlarged detail of the microelectromechanical mirror device of FIG. 1;

FIG. 3 shows the trend of the normalized deflection angle of a tiltable structure of the present microelectromechanical device as a function of structural parameters;

FIG. 4 is a plan view of a possible implementation of the microelectromechanical mirror device of FIG. 1;

FIG. 5 illustrates an enlarged detail of the microelectromechanical mirror device of FIG. 4;

FIG. 6 is a perspective view of the microelectromechanical mirror device of FIG. 4, in a rotated operative position;

FIG. 7 is a schematic plan view of a microelectromechanical mirror device, according to a different embodiment of the present solution;

FIG. 8 is a more detailed plan view of a possible implementation of the microelectromechanical mirror device of FIG. 7;

FIG. 9 illustrates an enlarged detail of the microelectromechanical mirror device of FIG. 7;

FIG. 10 is a schematic plan view of a microelectromechanical mirror device, according to another embodiment of the present solution; and

FIG. 11 is a block diagram of a pico-projector using the present microelectronic device.

### DETAILED DESCRIPTION

The following description refers to the arrangement shown; consequently, expressions such as “above,” “below,” “upper,” “lower,” “right,” “left” relate to the attached Figures and are not to be interpreted in a limiting manner.

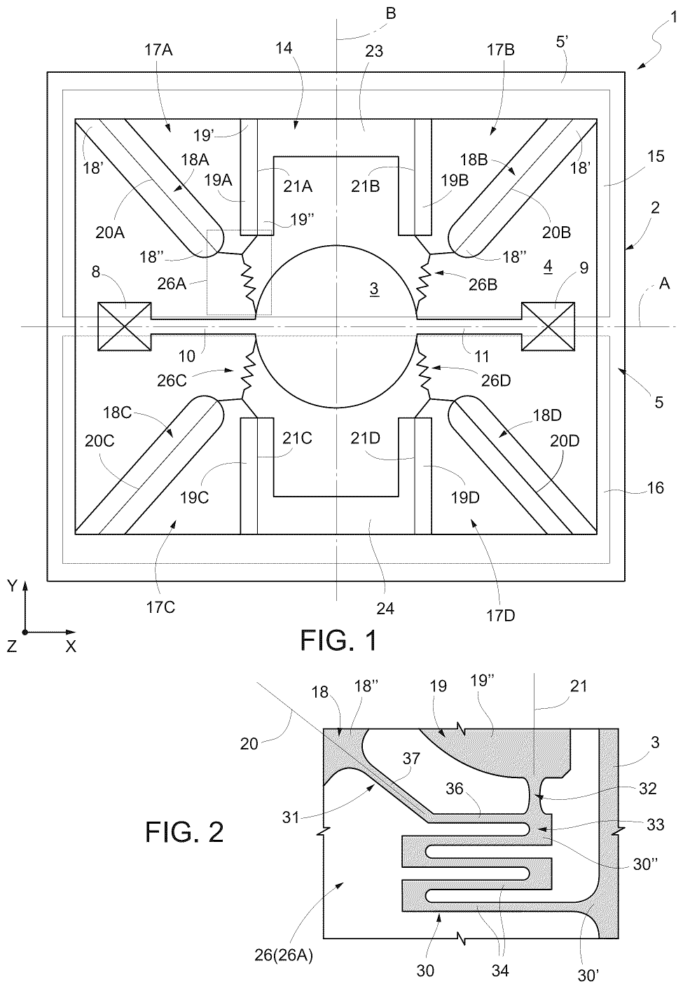

FIG. 1 schematically illustrates a microelectromechanical device 1, in particular a mirror device based on MEMS technology, here of the uniaxial type.

In particular, the microelectromechanical device 1 is configured so as to work in a quasi-static condition, i.e., with an oscillation frequency that is lower than its resonance frequency.

As described in detail below, in the microelectronic device 1, of the piezoelectric type, a first and a second actuation unit are coupled between a fixed structure and a tiltable structure, on a first side of a rotation axis, to control the rotation of the tiltable structure around the first rotation axis. Each actuation unit is formed by a first actuator, a second actuator and an elastic system. Each elastic system mutually couples the free ends of the respective first and second actuators to the tiltable structure.

In detail, the microelectromechanical device 1 is formed in a die 2 of semiconductor material, in particular silicon, and comprises a tiltable structure 3, having a main extension in a horizontal plane XY of a Cartesian coordinate system XYZ, having a first horizontal axis X, a second horizontal axis Y and a vertical axis Z.

The tiltable structure 3 has a substantially planar extension and is configured to rotate around a rotation axis A parallel to the first horizontal axis X.

The rotation axis A also represents a first median symmetry axis for the microelectromechanical device 1; a second median symmetry axis B for the microelectromechanical device 1 is parallel to the second horizontal axis Y and defines, with the first median symmetry axis A, the horizontal plane XY.

The tiltable structure 3 is suspended above a cavity 4, formed in the die 2, and has, in the illustrated embodiment, a generically circular or elliptical shape in the horizontal plane XY. In a known manner, the tiltable structure 3 defines a carrying structure, which carries at the top a reflecting surface (not shown), forming a mirror structure.

The tiltable structure 3 is elastically coupled to a fixed structure 5, defined in the same die 2. In particular, the fixed structure 5 forms, in the horizontal plane XY, a frame 5′ which delimits and surrounds the cavity 4.

Here the frame 5′ has a generally rectangular shape.

In particular, the tiltable structure 3 is coupled to a first and a second supporting element 8, 9 through a respective first and second elastic suspension element 10, 11. Here, the supporting elements 8, 9 are arranged at a distance from the frame 5′, on opposite sides of the tiltable structure 3. They may, however, also be connected to the frame 5′.

The elastic suspension elements 10, 11 here extend longitudinally, along the first median symmetry axis A, above the cavity 4, between the respective supporting element 8, 9 and the tiltable structure 3, and are coupled thereto at opposite peripheral portions, arranged along the first median symmetry axis A.

The elastic suspension elements 10, 11 are torsional elastic elements, with a high stiffness to movements out of the horizontal plane XY and yielding to torsion around the first horizontal axis X.

The elastic suspension elements 10, 11 then couple the tiltable structure 3 to the fixed structure 5, allowing the rotation thereof around the rotation axis A.

The microelectromechanical device 1 further comprises an actuation structure 14, coupled to the tiltable structure 3 and configured to cause its rotation around the rotation axis A; the actuation structure 14 is arranged between the tiltable structure 3 and the fixed structure 5 and also contributes to supporting the tiltable structure 3 above the cavity 4.

The actuation structure 14 here comprises a first and a second actuation portion, indicated by 15 and 16, arranged symmetrically with respect to the first median symmetry axis A and configured to be alternatively actuated to control the rotation of the tiltable structure 3 around the rotation axis A.

Each actuation portion 15, 16 is formed by two distinct actuation units, arranged symmetrically with respect to the second median symmetry axis B.

In detail, the first actuation portion 15 comprises a first actuation unit 17A and a second actuation unit 17B, the second actuation portion 16 comprises a third actuation unit 17C and a fourth actuation unit 17D.

The first and the second actuation units 17A, 17B are arranged symmetrically to each other with respect to the second median symmetry axis B; the third and the fourth actuation units 17C, 17D are arranged symmetrically to each other with respect to the second median symmetry axis B; the first and the third actuation units 17A, 17C are arranged symmetrically to each other with respect to the first median symmetry axis A; the second and the fourth actuation units 17B, 17D are arranged symmetrically to each other with respect to the first median symmetry axis A.

Each actuation unit 17A, 17B, 17C and 17D comprises a respective first actuator 18A, 18B, 18C, 18D; a respective second actuator 19A, 19B, 19C, 19D; and a respective elastic system 26A, 26B, 26C, 26D.

In each of the actuation units 17A-17D, the first actuator 18A-18D operates along a different direction with respect to the respective second actuator 19A-19D.

In particular, the first actuators 18A-18D have respective effective actuation directions 20A-20D which extend transversally to both the first and the second median symmetry axes A, B.

In detail, the first actuators 16A-16D have an elongated shape and extend from the frame 5′ (approximately from respective edges thereof, at a respective constraint end 18′) towards the tiltable structure 3 (internal end 18″).

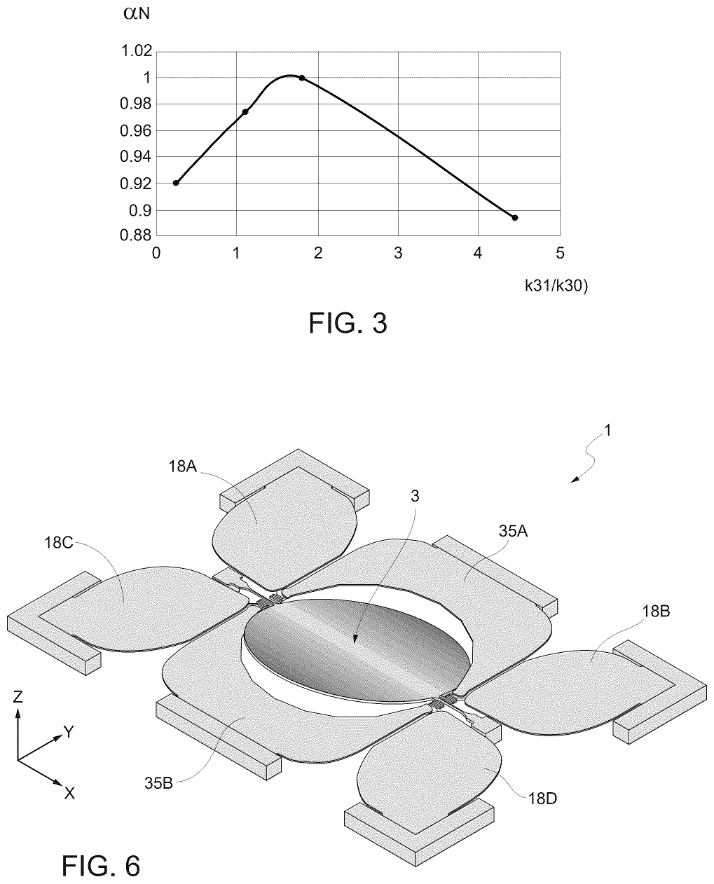

In the schematic representation of FIG. 1, the first actuators 16A-16D are represented as straight arms, but they may have a different shape, in particular a convex, “leaf” shape, as discussed below with reference to FIG. 3.

The second actuators 19A-19D have respective effective actuation directions 21A-21D which extend transversely to the first median symmetry axis A. In the schematic representation of FIG. 1, the second actuators 19A-19D have effective actuation directions 21A-21D substantially parallel to each other and to the second median symmetry axis B, however this is not essential.

Conversely, to obtain an efficient operation, it is sufficient that, in each actuation unit 17A-17D, the effective actuation direction of the second actuator 19A-19D forms a non-zero angle with the effective actuation direction of the respective first actuator 18A-18D.

In detail, the second actuators 19A-19D have an elongated shape and extend, from zones of the frame 5′ intermediate with respect to the edges (at a respective constraint end 19′), towards the tiltable structure 3 (internal end 19″).

In the schematic representation of FIG. 1, the second actuators 19A-19D are represented as straight arms, but they may have different shape, in particular an “apostrophe” or “comma” shape, as discussed below with reference to FIG. 3.

The second actuator 19A of the first actuation unit 17A and the second actuator 19B of the second actuation unit 17B may be connected to each other by a first transversal actuation portion 23, having an extension direction generally parallel to the first median symmetry axis A and coupled, at a longitudinal side thereof, to the frame 5′.

The second actuator 19A of the first actuation unit 17A, the second actuator 19B of the second actuation unit 17B and the first transversal actuation portion 23 therefore form a C-shaped actuation element with a concavity facing the tiltable structure 3.

Similarly, the second actuator 19C of the third actuation unit 17C and the second actuator 19D of the fourth actuation unit 17D may be connected to each other by a second transversal actuation portion 24, having an extension direction generally parallel to the first median symmetry axis A and coupled at a longitudinal side thereof to the frame 5′, on a side of the latter which is opposite to the coupling side of the first transversal actuation portion 23.

The second transversal actuation portion 24 is therefore symmetrical to the first transversal actuation portion 23 with respect to the first median symmetry axis A and forms here, with the second actuator 19C of the third actuation unit 17C and the second actuator 19D of the fourth actuation unit 17D, a C-shaped actuation element, with a concavity facing the tiltable structure 3.

In a manner not shown, all actuation units 17A-17D are formed in a same structural layer of semiconductor material, typically silicon, and are suspended above the cavity 4; the first and the second actuators 18A-18D, 19A-19D typically carry, on their upper surfaces, respective piezoelectric regions, not shown, for example of a material based on PZT-Lead Zirconate Titanate or other piezoelectric material.

The elastic systems 26A-26D are shown schematically in FIG. 1 and couple the internal end 18″ of the first actuator 18A-18D to the internal end 19″ of the respective second actuator 19A-19D of each actuation unit 17A-17D and to the tiltable structure 3 as described hereinbelow with reference to FIG. 2.

FIG. 2 shows, on an enlarged scale, the first elastic system 26A of the first actuation portion 15.

However, due to the symmetry of the elastic systems 26A-26D, their structure, their features, their connection and their operating manner are equivalent, only the direction and the working point changing. Consequently, in FIG. 2, the elastic system 26A is also indicated simply by 26, the first actuator is indicated by 18, the second actuator is indicated by 19; the first effective actuation direction is indicated by 20 and the second effective actuation direction is indicated by 21. Furthermore, what described below applies to all elastic systems 26A-26D.

In detail, the elastic system 26 comprises a folded spring 30, a bending spring 31 and a connection section 32.

The folded spring 30 has a first end 30′ coupled (here, attached) to the tiltable structure 3, in proximity to a peripheral portion thereof close to the coupling point with the first elastic suspension element 10 (as better visible in FIG. 1).

The folded spring 30 also has a second end 30″, coupled to the bending spring 31 and to the connection section 32 and forming a common node therewith, indicated hereinbelow by 33.

In this embodiment, the folded spring 30 has a general extension that is parallel to the second median symmetry axis B and is formed by a plurality of spring sections 34 parallel to each other and to the first median symmetry axis A, so as to transfer the out-of-plane displacement of the actuation units 17A-17D into a rotation of the tiltable structure 3.

The bending spring 31 is here formed by two spring sections: a first spring section 36, coupled to the common node 33, and a second spring section 37, coupled to the internal end 18″ of the respective first actuator 18.

Here, the first spring section 36 of the bending spring 31 is parallel to the first median symmetry axis A (and therefore to the spring sections 34 of the folded spring 30), and the second spring section 37 of the bending spring 31 is parallel to the effective actuation direction 20 of the respective first actuator 18.

The connection section 32 is of minimum length and is substantially stiff (for example it has at least four times the stiffness of the folded spring 30) and couples the internal end 19″ of the second actuator 19 to the common node 33.

The elastic system 26 is configured so that the folded spring 30 has higher yielding than the bending spring 31 or, in other words, that the stiffness of the bending spring 31 is higher than the stiffness of the folded spring 30.

Furthermore, since the set of “first actuator 18+bending spring 31” is coupled to the set of “second actuator 19+connection section 32” at the second end 30″ of the folded spring 30 (common node 33), they have a same effective length.

In use, the first actuation portion 15 and the second actuation portion 16 are actuated alternatively, providing suitable biasing voltages (for example, equal to each other, of 40 V, or different) to the respective first and second actuators 18A-18D, 19A-19B which deflect, causing corresponding movements out of the horizontal plane XY of their internal ends 18″, 19″.

Furthermore, the elastic suspension elements 10, 11 twist, allowing the tiltable structure 3 to rotate.

Thanks to the combined action along two different effective directions by the first and the second actuators 18, 19 of each actuation unit 17A-17D and to the presence of an elastic system 26 which couples their internal ends 18″, 19″ at the common node 33, high actuation efficiency is obtained.

In particular, studies by the Applicant have shown that an improvement in the performances of the microelectromechanical device 1 may be obtained when, as indicated above, the stiffness of the bending spring 31 is greater than the stiffness of the folded spring 30.

Specifically, it has been seen that the elastic system 26 has maximum efficiency when the ratio k31/k30 between the stiffness k31 of the bending spring 31 and the stiffness k30 of the folded spring 30 is greater than 1 and comprised for example between 1.2 and 10, in particular between 1.5 and 4.

This is shown in the plot of FIG. 3, representing the trend of the normalized deflection angle αN as a function of the ratio k31/k30, wherein the normalized deflection angle αN represents the angle of the tiltable structure 3 normalized to the maximum value obtainable with a test structure.

In particular, the studied test structure allows to obtain a maximum value of the rotation of the tiltable structure 3 equal to 13.5°.

The arrangement of the second spring section 37 of the bending spring 31 of each actuation unit 16A-16D parallel to the effective actuation direction of the respective first actuator 18A-18D allows an effective transfer of the force generated by the first actuator 18 towards the second end 30″ of the folded spring 30, while the first spring section 36 has a connection function.

The connection of the bending spring 31 to the second end 19″ of the second actuator 19, at the common node 33, through the connection section 32, allows the application of the force generated by the two actuators 18, 19, in common mode, on the second end 30″ of the folded spring 30.

The deformation of the bending spring 31, the (more limited) deformation of the connection section 32 and the deformation of the folded spring 30 allow the transformation of the vertical movement of the ends of the first and the second actuators 18, 19 into a rotation of the tiltable structure 3 and the out-of-plane movement thereof along the vertical axis Z, in a particularly efficient manner.

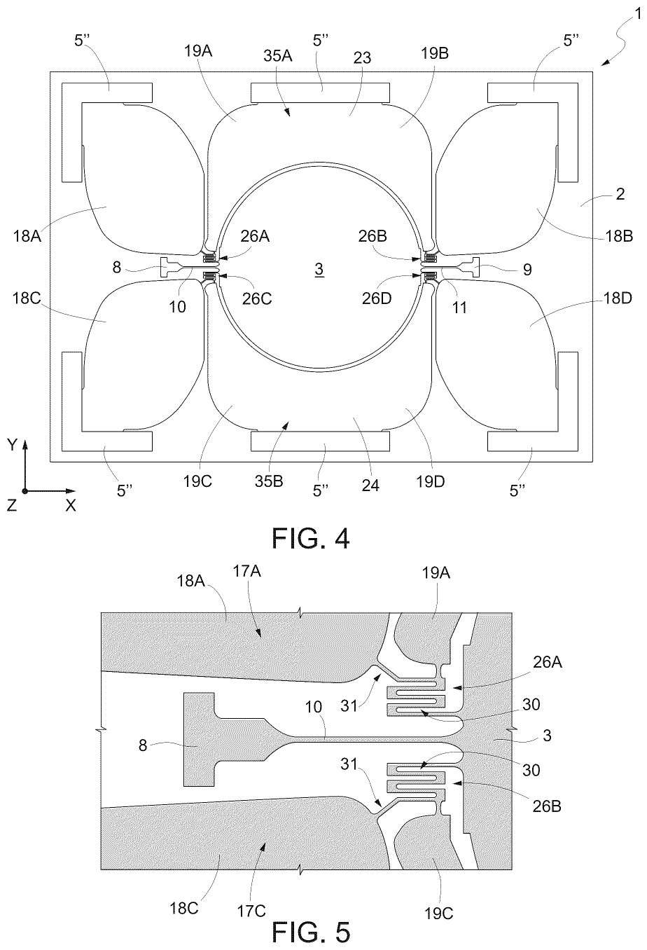

FIGS. 4 and 5 show an embodiment of the micromechanical device 1.

In particular, in this embodiment, for which the same reference numbers as in FIG. 1 have been used, the first actuators 18A-18D have a lanceolate, “leaf” shape.

Furthermore, the second actuators 19A-19D have a pointed rounded, “apostrophe” or “comma,” shape with a concavity facing the tiltable structure 3, so that the second actuators 19A, 19B of the first and the second actuation units 17A, 17B form, with the first transversal actuation portion 23, a single actuation element 35A and the second actuators 19C, 19D of the third and the fourth units 17C, 17D form, with the second transversal actuation portion 24, a single actuation element 35B.

In this manner, a maximization of the area of the actuators 18A-18D, 19A-19D is obtained, with the same external size.

Here, the actuators 18A-18D, 19A-19D are anchored in distinct anchoring zones, indicated by 5″, arranged along an ideal rectangular frame.

FIG. 6 is a view of the micromechanical device 1 of FIGS. 4 and 5 in the rotated position of the tiltable structure 3.

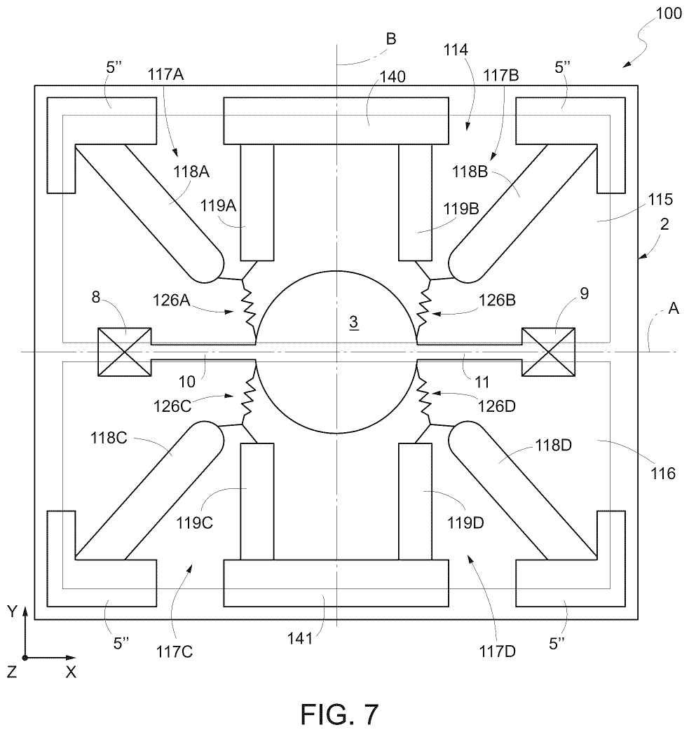

FIG. 7 shows a micromechanical device 100 having an actuation structure 114 whose first actuators (indicated by 118A-118D) and second actuators (indicated by 119A-119D) of the actuation units (indicated by 117A, 117B) are not joined by transversal actuation portions, but are distinct.

The second actuator 119A of the first actuation unit 117A and the second actuator 119B of the second actuation unit 117B (second actuators of the first actuation portion, indicated by 115) may, however, be coupled to a same first anchoring zone or to a same frame portion, indicated by 140; the second actuator 119C of the third actuation unit 117C and the second actuator 119D of the fourth actuation unit 117D (second actuators of the second actuation portion, indicated by 116) may be coupled to a same second anchoring zone, indicated by 141.

The other elements of the micromechanical device 100 are similar to those of the micromechanical device 1 of FIG. 1 and have therefore been identified by the same reference numbers.

Here, by virtue of the mutual separation of the second actuators 119A, 119B of the first actuation portion 115 and the mutual separation of the second actuators 119C, 119D of the second actuation portion 116, the tiltable structure 3 may have a very large area.

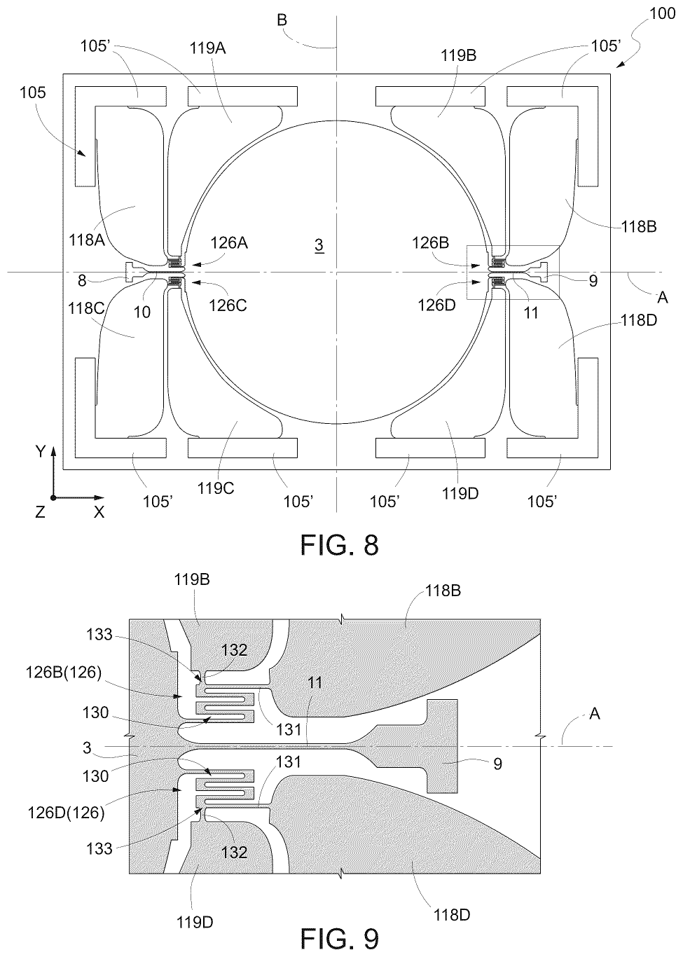

Furthermore, the mutual separation of the second actuators 119A, 119B of the first actuation portion 115 and of the second actuators 119C, 119D of the second actuation portion 116 allows an increase in stiffness caused by the transversal actuation portions 23, 24 (which should be formed thin but would not contribute to a significant increase in the actuation force) to be reduced. FIGS. 8 and 9 show a possible embodiment of the micromechanical device 100.

Here, the first actuators 118A-118D and the second actuators 119A-119D have proportionally much smaller size compared to the first actuators 18A-18B and the second actuators 19A-19D of FIGS. 4-6, allowing, as mentioned, the tiltable structure 3 of large size, such as to occupy a considerable portion of the area of the die 2, to be formed.

Furthermore, the elastic systems (here indicated by 126A-126D) have a slightly different shape compared to the elastic systems 26A-26D of FIG. 2, to take into account the different proportions of the micromechanical device 100.

In particular, as shown in FIG. 9, illustrating in detail the configuration of the second and the fourth elastic systems 126B, 126D, each elastic system 126 is again formed by a folded spring, indicated by 130, by a bending spring, here indicated by 131, and by a connection section, here indicated by 132. The common nodes are indicated by 133.

Here, the bending spring 131 is formed by a single straight section, extending parallel to the first median symmetry axis A. Although less optimal than the solution of FIGS. 3-5, this arrangement allows a reduction of area.

Furthermore, the second actuators 19A-119D are anchored to distinct anchoring zones 105′, forming part of a fixed structure 105.

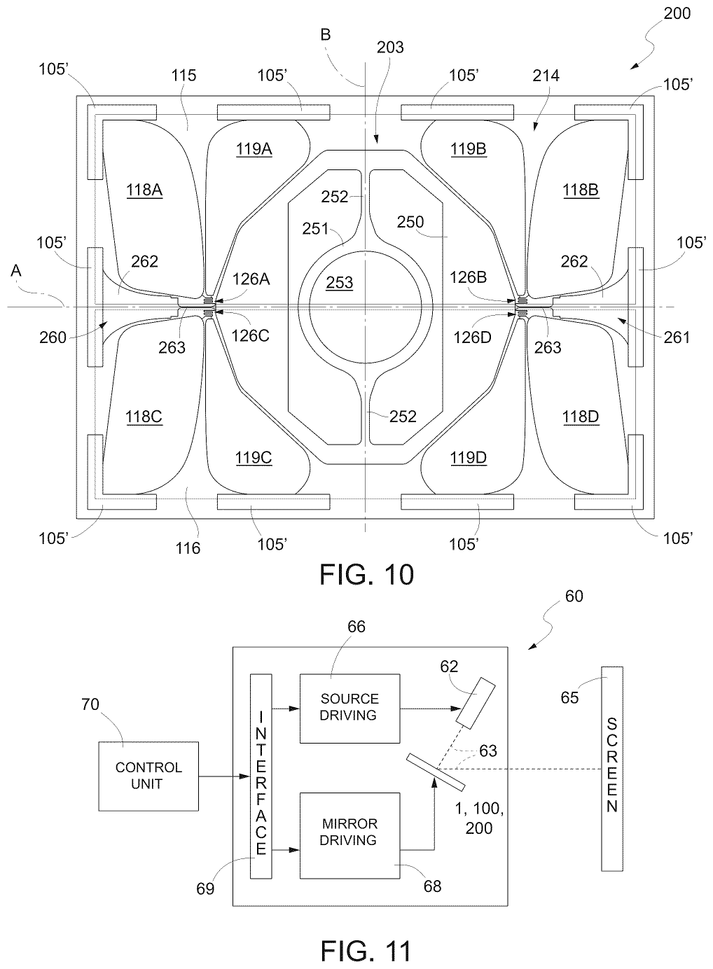

FIG. 10 shows a micromechanical device 200 of the biaxial type, for example for performing raster scanning movements in an optical projection system.

In this case, the actuation structure, indicated by 214, allows to provide not only the rotation around the first symmetry axis A (here forming a first rotation axis indicated again by A) and relative to a slow axis, typically for vertical scanning in raster scanning, but also a rotation around the second symmetry axis B (here forming a second rotation axis indicated again by B) and relative to a fast axis, typically for horizontal scanning in raster scanning.

In this case, the micromechanical device 200 has a general structure as described in Italian patent 102022000004745 mentioned above.

In particular, in FIG. 10, the tiltable structure (here indicated by 203) is formed by a decoupling frame 250 carrying a rotatable platform 251 having main extension in the horizontal plane XY and suspended on the cavity 4 through coupling elastic elements 252.

Here, the coupling elastic elements 252 generally extend along the second symmetry axis B and are yielding to torsion around that axis (second rotation axis B).

Furthermore, in the embodiment shown, the rotatable platform 251 carries a reflecting surface 253.

In FIG. 10, the actuation structure 214 comprises a first and a second fast actuation element 260, 261 arranged on opposite sides of the tiltable structure 203 with respect to the second symmetry axis B.

Each fast actuation element 260, 261 in turn comprises an actuation arm 262, of piezoelectric type and anchored to respective anchoring zones 105′, and elastic suspension elements 263, extending between the respective actuation arms 262 and the decoupling frame 250, according to what described in detail in aforementioned Italian patent 102022000004745.

In FIG. 10, the actuation structure 214 further comprises a first and a second actuation portion of the type described with reference to the micromechanical device 100 of FIGS. 7-9, and therefore indicated again by 115, 116; however, the first and the second actuation portions might be formed like the actuation portions 15, 16 of the micromechanical device 1 of FIGS. 4-6.

By virtue of the described solutions, the microelectromechanical device 1; 100; 200 has a high actuation efficiency, with efficient space occupation and optimized size of the actuation part.

Advantageously, the microelectromechanical device 1, 100, 200 may be used in a pico-projector 60 conformed to be functionally coupled to a portable electronic apparatus, as illustrated schematically with reference to FIG. 11.

In particular, in FIG. 11, the pico-projector 60 comprises a light source 62, for example of a laser type, conformed to generate a light beam 63; the microelectronic device 1, 100, 200, acting as a mirror and conformed to receive the light beam 63 and direct it towards a screen or display surface 65 (external to, and arranged at a distance from, the same pico-projector 60); a first driving circuit 66, conformed to provide appropriate control signals to the light source 62, for generation of the light beam 63 as a function of an image to be projected; a second driving circuit 68, conformed to provide driving signals to the actuation structure 14, 214 of the microelectronic device 1, 100, 200; and a communication interface 69, conformed to receive, from a control unit 70, that is external, for example included in the portable apparatus (not shown), information on the image to be generated, for example in the form of a pixel array. This information is sent as an input for driving the light source 62.

Finally, it is clear that modifications and variations may be made to the microelectronic device described and illustrated herein without thereby departing from the scope of the present disclosure. For example, the different embodiments described may be combined to provide further solutions.

Furthermore, the exact shape of the structures, including the actuators, the anchoring zones, of the coupling elastic systems, may vary from what shown.

A microelectronic device (1; 100; 200) of piezoelectric type, may be summarized as including: a fixed structure (5; 105) including anchoring regions (5′; 5″; 105′) and delimiting a cavity (4); a tiltable structure (3; 203) having main extension in a horizontal plane (XY) and suspended on the cavity (4); an elastic supporting structure (8-11; 260, 261), including a first and a second elastic suspension element (10, 11; 263) extending between the fixed structure (5; 105) and respective opposite supporting points of the tiltable structure (3; 203), the first and the second elastic suspension elements defining a first rotation axis of the tiltable structure; an actuation structure (14; 114; 214), including a first actuation portion (15; 115) coupled between the fixed structure and the tiltable structure (3; 203), on a first side of the first rotation axis (A), and configured to cause the rotation of the tiltable structure around the first rotation axis (A), wherein the first actuation portion (15; 115) comprises a first actuation unit (17A; 117A) and a second actuation unit (17B; 117B), each actuation unit including a first actuator (18, 18A, 18B; 118A, 118B), a second actuator (19, 19A, 19B; 119A, 119B) and an elastic system (26, 26A, 26B; 126, 126A, 126B), the first and the second actuators (18, 18A, 18B; 118A, 118B, 19, 19A, 19B; 119A, 119B) of each actuation unit (5; 105) having a respective first portion (18′, 19′) coupled to the fixed structure and a respective second portion (18″; 19″) coupled to the respective elastic system (26, 26A, 26B; 126, 126A, 126B), the elastic system (26, 26A; 126, 126A) of the first actuation unit (17A; 117A) mutually coupling the second portion (18″) of the first actuator (18, 18A; 118A) of the first actuation unit (17A; 117A), the second portion (19″) of the second actuator (19, 19A; 119A) of the first actuation unit (17A; 117A) and the tiltable structure (3; 203), the elastic system (26, 26B; 126, 126B) of the second actuation unit (17B; 117B) mutually coupling the second portion (18″) of the first actuator (18, 18B; 118B) of the second actuation unit (17B; 117B), the second portion (19″) of the second actuator (19, 19B; 119B) of the second actuation unit (17B; 117B) and the tiltable structure (3; 203).

The first actuation unit (17A; 117A) and the second actuation unit (17B; 117B) are arranged symmetrically with respect to a symmetry axis (B) perpendicular to the first rotation axis (A).

Each first actuator (18, 18A, 18B; 118A, 118B) of each actuation unit (17A, 17B; 117A, 117B) defines a respective first effective actuation direction (20A, 20B), the second actuator (19, 19A, 19B; 119A, 119B) of each actuation unit defines a respective second effective actuation direction (21A, 21B), the first effective actuation direction (20A) of the first actuation unit (17A; 117A) may be different from the second effective actuation direction (21A) of the first actuation unit, and the first effective actuation direction (20B) of the second actuation unit (17B; 117B) may be different from the second effective actuation direction (21B) of the second actuation unit.

The elastic system (26, 26A, 26B; 126, 126A, 126B) of each actuation unit (17A, 17B; 117A, 117B) comprises a first elastic element (30) and a second elastic element (31), the first elastic element (30) of the first actuation unit (17A; 117A) having a first end (30′) coupled to the tiltable structure (3; 203) and a second end (30″) coupled to a first common node (33), the first elastic element (30) of the second actuation unit (17B; 117B) having a first end (30′) coupled to the tiltable structure (3; 203) and a second end (30″) coupled to a second common node (33), the second elastic element (31) of the first actuation unit (17A; 117A) having a first end coupled to the first common node (33) and a second end coupled to the second portion (18″) of the first actuator (18, 18A, 118A) of the first actuation unit (17A; 117A), the second elastic element (31) of the second actuation unit (17B; 117B) having a first end coupled to the second common node (33) and a second end coupled to the second portion (18″) of the first actuator (18, 18B, 118B) of the second actuation unit (17B; 117B).

In each actuation unit (17A, 17B; 117A, 117B), the first elastic element (30) has a first stiffness, and the second elastic element (31) has a second stiffness, the second stiffness being greater than the first stiffness.

A ratio between the first and the second stiffness is comprised between 1.2 and 10, in particular between 1.5 and 4.

The first elastic elements (30) of the first and the second actuation units (17A, 17B; 117A, 117B) are springs of the folded type.

The first elastic elements (30) of the first and the second actuation units (17A, 17B; 117A, 117B) extend perpendicularly to the first rotation axis (A).

The device further comprising a connection section (32) extending between the first node (33) and the second portion (19″) of the second actuator (19, 19A, 19B; 119A, 119B) of each actuation unit (17A, 17B; 117A, 117B), the connection section (32) having greater stiffness than the respective first and second elastic elements (30, 31).

The first actuator (18, 18A, 18B; 118A, 118B) of the first and the second actuation units (17A, 17B; 117A, 117B) have an elongated shape, and the second elastic element 31 of the first and the second actuation units (17A, 17B; 117A, 117B) has a section 37 having an extension direction generally parallel to the respective first effective actuation direction (20A, 20B).

The second actuators (19A, 19B) of the first and the second actuation units (17A, 17B) are mutually coupled at the respective first portions (19′) and form a single actuation element (35A) having a C shape and concavity facing the tiltable structure (3).

The actuation structure (14; 140; 240) comprises a second actuation portion (16; 116) coupled between the fixed structure (5; 105) and the tiltable structure (3; 203), on a second side of the first rotation axis (A), the second actuation portion (16; 116) being symmetrical to the first actuation portion (15; 115) with respect to the first rotation axis, the first and the second actuation portions cooperating to cause the rotation of the tiltable structure around the first rotation axis (A) in opposite directions.

The tiltable structure (203) comprises a decoupling frame (250) carrying a rotatable platform (251) having main extension in the horizontal plane (XY) and suspended on the cavity (4) through coupling elastic elements (252) yielding to torsion around a second rotation axis (B) transversal with respect to the first rotation axis (A).

The fixed structure (5; 105) comprises a generally rectangular bearing structure (5′; 5″; 105′) having a plurality of edges, the first actuators (18, 18A, 18B; 118A, 118B) of the first and the second actuation units (17A, 17B; 117A, 117B) extend from portions of the fixed structure close to respective edges and the second actuators (19, 19A, 19B; 119A, 119B) of the first and the second actuation units (17A, 17B; 117A, 117B) extend from portions of the bearing structure (5′; 5″; 105′) intermediate between two adjacent edges.

An electronic apparatus (50) may be summarized as including the microelectromechanical device (1; 100; 200).

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A microelectronic device of piezoelectric type, the microelectronic device comprising:
a fixed structure including anchoring regions and delimiting a cavity;
a tiltable structure having main extension in a horizontal plane and suspended over the cavity;
an elastic supporting structure including a first and a second elastic suspension element extending between the fixed structure and respective opposite supporting points of the tiltable structure, the first and the second elastic suspension elements defining a first rotation axis of the tiltable structure;
an actuation structure including a first actuation portion coupled between the fixed structure and the tiltable structure, on a first side of the first rotation axis, and configured to cause rotation of the tiltable structure around the first rotation axis,
wherein the first actuation portion includes a first actuation unit and a second actuation unit,
each of the first and second actuation units including a first actuator, a second actuator, and an elastic system,
the first and the second actuators of each of the first and second actuation units having a respective first portion coupled to the fixed structure and a respective second portion coupled to the respective elastic system,
the elastic system of the first actuation unit mutually coupling the second portion of the first actuator of the first actuation unit, the second portion of the second actuator of the first actuation unit, and the tiltable structure, and
the elastic system of the second actuation unit mutually coupling the second portion of the first actuator of the second actuation unit, the second portion of the second actuator of the second actuation unit, and the tiltable structure.

2. The microelectronic device according to claim 1, wherein the first actuation unit and the second actuation unit are arranged symmetrically with respect to a symmetry axis perpendicular to the first rotation axis.

3. The microelectronic device according to claim 1, wherein:
each first actuator of each of the first and second actuation units defines a respective first effective actuation direction, and each second actuator of each actuation unit defines a respective second effective actuation direction,
the first effective actuation direction of the first actuation unit is different from the second effective actuation direction of the first actuation unit, and
the first effective actuation direction of the second actuation unit is different from the second effective actuation direction of the second actuation unit.

4. The microelectronic device according to claim 1, wherein the elastic system of each of the first and second actuation units includes a first elastic element and a second elastic element,
the first elastic element of the first actuation unit having a first end coupled to the tiltable structure and a second end coupled to a first common node,
the first elastic element of the second actuation unit having a first end coupled to the tiltable structure and a second end coupled to a second common node,
the second elastic element of the first actuation unit having a first end coupled to the first common node and a second end coupled to the second portion of the first actuator of the first actuation unit,
the second elastic element of the second actuation unit having a first end coupled to the second common node and a second end coupled to the second portion of the first actuator of the second actuation unit.

5. The microelectronic device according to the claim 4, wherein, in each of the first and second actuation units, the first elastic element has a first stiffness, and the second elastic element has a second stiffness, the second stiffness being greater than the first stiffness.

6. The microelectronic device according to the claim 5, wherein a ratio between the first and the second stiffness is between 1.2 and 10.

7. The microelectronic device according to claim 4, wherein the first elastic elements of the first and the second actuation units are springs of a folded type.

8. The microelectronic device according to the claim 7, wherein the first elastic elements of the first and the second actuation units extend perpendicularly to the first rotation axis.

9. The microelectronic device according to claim 4, further comprising:
a connection section extending between the first common node and the second portion of the second actuator of each of the first and second actuation units, the connection section having greater stiffness than the respective first and second elastic elements.

10. The microelectronic device according to claim 4, wherein
each first actuator of each of the first and second actuation units defines a respective first effective actuation direction, and each second actuator of each actuation unit defines a respective second effective actuation direction, and
the first actuator of the first and the second actuation units has an elongated shape, and the second elastic element of the first and the second actuation units has a section having an extension direction substantially parallel to the respective first effective actuation direction.

11. The microelectronic device according to claim 1, wherein the second actuators of the first and the second actuation units are mutually coupled at the respective first portions and form a single actuation element having a C shape and concavity facing the tiltable structure.

12. The microelectronic device according to claim 1, wherein the actuation structure includes a second actuation portion coupled between the fixed structure and the tiltable structure, on a second side of the first rotation axis, the second actuation portion being symmetrical to the first actuation portion with respect to the first rotation axis, the first and the second actuation portions cooperating to cause the rotation of the tiltable structure around the first rotation axis in opposite directions.

13. The microelectronic device according to claim 1, wherein the tiltable structure includes a decoupling frame carrying a rotatable platform having a main extension in the horizontal plane and suspended over the cavity through coupling elastic elements yielding to torsion around a second rotation axis transversal with respect to the first rotation axis.

14. The microelectronic device according to claim 1, wherein the fixed structure includes a substantially rectangular bearing structure having a plurality of edges, the first actuators of the first and the second actuation units extend from portions of the fixed structure close to respective edges, and the second actuators of the first and the second actuation units extend from portions of the bearing structure intermediate between two adjacent edges.

15. An electronic apparatus, comprising:
a microelectromechanical device including:
a fixed structure including anchoring regions and delimiting a cavity;
a tiltable structure having main extension in a horizontal plane and suspended over the cavity;
an elastic supporting structure including a first and a second elastic suspension element extending between the fixed structure and respective opposite supporting points of the tiltable structure, the first and the second elastic suspension elements defining a first rotation axis of the tiltable structure;
an actuation structure including a first actuation portion coupled between the fixed structure and the tiltable structure, on a first side of the first rotation axis, and configured to cause rotation of the tiltable structure around the first rotation axis,
wherein the first actuation portion includes a first actuation unit and a second actuation unit,
each of the first and second actuation units including a first actuator, a second actuator, and an elastic system,
the first and the second actuators of each of the first and second actuation units having a respective first portion coupled to the fixed structure and a respective second portion coupled to the respective elastic system,
the elastic system of the first actuation unit mutually coupling the second portion of the first actuator of the first actuation unit, the second portion of the second actuator of the first actuation unit, and the tiltable structure, and
the elastic system of the second actuation unit mutually coupling the second portion of the first actuator of the second actuation unit, the second portion of the second actuator of the second actuation unit, and the tiltable structure.

16. The electronic apparatus according to claim 15, wherein the first actuation unit and the second actuation unit are arranged symmetrically with respect to a symmetry axis perpendicular to the first rotation axis.

17. The electronic apparatus according to claim 15, wherein:
each first actuator of each of the first and second actuation units defines a respective first effective actuation direction, and each second actuator of each actuation unit defines a respective second effective actuation direction,
the first effective actuation direction of the first actuation unit is different from the second effective actuation direction of the first actuation unit, and
the first effective actuation direction of the second actuation unit is different from the second effective actuation direction of the second actuation unit.

18. A device comprising:
a fixed structure;
elastic suspension elements;
a tiltable structure coupled to the fixed structure by the elastic suspension elements;
first, second, third, and fourth elastic systems; and
an actuation structure including:
a first actuation portion coupled between the fixed structure and the tiltable structure, on a first side of the tiltable structure, the first actuation portion including first, second, third, and fourth actuators, the first and second actuators coupled to the tiltable structure by the first elastic system, the third and fourth actuators coupled to the tiltable structure by the second elastic system; and
a second actuation portion coupled between the fixed structure and the tiltable structure on a second side, opposite to the first side, of the tiltable structure, the second actuation portion including fifth, sixth, seventh, and eight actuators, the fifth and sixth actuators coupled to the tiltable structure by the third elastic system, the seventh and eighth actuators coupled to the tiltable structure by the fourth elastic system.

19. The device according to claim 18, wherein
the first elastic system includes a first elastic element, a second elastic element, and a connection section,
the first elastic element is coupled between the tiltable structure, the first elastic element, and the connection section,
the second elastic element is coupled to the first actuator, the first elastic element, and the connection section, and
the connection section is coupled to the second actuator, the first elastic element, and the second elastic element.

20. The device according to the claim 19, wherein the first elastic element has a first stiffness, and the second elastic element has a second stiffness greater than the first stiffness.
